(19) United States
(12) Patent Application Publication
(10) Pub. No.: US 2026/0367126 A1
(43) Pub. Date: Nov. 19, 2026

(54) METHODS AND SYSTEMS FOR DETERMINING S-PARAMETERS OF A DEVICE UNDER-TEST

(71) Applicant: Rohde & Schwarz GmbH & Co. KG, Munich (DE)

(72) Inventors: Kai-Uwe SCHMIDT, Munich (DE); Walter WEISS, Poing (DE)

(21) Appl. No.: 19/096,145

(22) Filed: Mar. 31, 2025

(51) Int. Cl. G01R 29/08; H04B 17/00

(52) U.S. Cl. CPC G01R 29/0892; H04B 17/0085

(57) ABSTRACT

The present disclosure relates to a method for determining mixed-mode S-parameters of a device-under-test, DUT. The method comprises the steps of: performing a number of S-parameter measurements with the DUT to determine a subset of single ended S-parameters of the DUT, wherein the subset excludes single ended crosstalk S-parameters; approximating the single ended crosstalk S-parameters of the DUT based on a model of the DUT or based on an assumption; and calculating the mixed-mode S-parameters of the DUT based on the measured subset of single ended S-parameters and based on the approximated single ended crosstalk S-parameters.

### TECHNICAL FIELD

The present disclosure relates to the determination of S-parameters of a device-under-test, in particular mixed-mode S-parameters and single ended S-parameters.

### BACKGROUND ART

Scattering parameters (S-parameters) characterize the electrical behavior of electrical devices or networks when stimulated by electrical signals. They are an important tool in RF engineering, e.g., for designing or testing electrical circuits.

S-parameters can be expressed in terms of single ended S-parameters and mixed-mode S-parameters. Single ended S-parameters consider how a signal at one port of the device or network influences another port (without differential operation) and are typically measured from one port to another. Mixed-mode S-parameters in contrast describe the response of the network or device to common mode and differential stimulus signals.

However, measuring such S-parameters can be cumbersome and require complex measurement equipment, especially if a device under test has multiple ports (e.g., four ports or more).

Accordingly, there is a need to provide a method and a system for determining S-parameters of a device-under test in a faster and more efficient manner.

### SUMMARY

According to a first aspect, the present disclosure relates to a method for determining mixed-mode S-parameters of a device-under-test (DUT). The method comprises the steps of: performing a number of S-parameter measurements with the DUT to determine a subset of single ended S-parameters of the DUT, wherein the subset excludes single ended crosstalk S-parameters; approximating the single ended crosstalk S-parameters of the DUT based on a model of the DUT or based on an assumption; and calculating the mixed-mode S-parameters of the DUT based on the measured subset of single ended S-parameters and based on the approximated single ended crosstalk S-parameters.

This achieves the advantage that only a subset of the single ended S-parameter, e.g. the transmission and/or reflection parameters, are measured to determine the mixed-mode S-parameters. The remaining single ended S-parameter, i.e. the crosstalk S-parameters, are only approximated, saving measurement time and reducing the required measurement resources.

For instance, the DUT can be or can comprise well characterized electric components (e.g., a well-known cable), such that the crosstalk S-parameters, which are typically non-dominant parameters, can be considered as ideal or set to a fixed value (e.g., zero).

The mixed-mode S-parameters can be calculated from the calculated and approximated single ended S-parameters based on conversion equations.

In an implementation form, the measured subset of single ended S-parameters comprises single ended transmission S-parameters and/or single ended reflection S-parameters.

Typically, the transmission S-parameters characterize the intended signal paths through the DUT and the reflection S-parameters characterize the reflection from the DUT ports. The crosstalk S-parameters characterize unwanted signal coupling into adjacent signal lines in the DUT. The crosstalk S-parameters can be separated in near-end crosstalk (NEXT) and far-end crosstalk (FEXT) parameters.

For instance, if the DUT is a four port device with ports 1, 2, 3 and 4, the transmission S-parameters refer to the S₁₂, S₂₁, S₃₄ and S₄₃ coefficients, the reflection S-parameters refer to the S₁₁, S₂₂, S₃₃ and S₄₄ coefficients, and the crosstalk S-parameters refer to the S₁₃, S₁₄, S₂₃, S₂₄, S₃₁, S₃₂, S₄₁ and S₄₂ coefficients.

In an implementation form, the mixed-mode S-parameters comprise differential-to-differential parameters, common-to-common parameters, differential-to-common parameters, and/or common-to-differential parameters. These S-mode parameters can be referred to as S_{dd}, S_{cc}, S_{dc} and S_{cd} parameters.

The mixed-mode parameters may comprise only the differential S-parameters parameters (S_{dd} and S_{cc}) or the differential S-parameters and the mode conversion S-parameters (S_{dc}, S_{cd}).

In an implementation form, the single ended crosstalk S-parameters are approximated to be zero.

In an implementation form, the method further comprises: verifying the approximated single ended crosstalk S-parameters by correlating them with results of a characterization measurement performed with the DUT.

In an implementation form, the DUT is a digital design test (DDT) DUT.

In an implementation form, the DUT is a four-port device.

In an implementation form, the steps of the method are carried out by a vector network analyzer. For instance, the vector network analyzer has at least four measurement ports which are connected to the respective ports of the DUT for performing the number of measurements.

According to a second aspect, the present disclosure relates to a system for determining mixed-mode S-parameters of a device-under-test (DUT). The system comprises: a number of ports arranged for being connected to the DUT; a measurement unit configured to perform a number of S-parameter measurements with the DUT to determine a subset of single ended S-parameters of the DUT, wherein the subset excludes single ended crosstalk S-parameters; and a processor configured to approximate the single ended crosstalk S-parameters of the DUT based on a model of the DUT or based on an assumption; wherein the processor is configured to calculate the mixed-mode S-parameters of the DUT based on the measured subset of single ended S-parameters and based on the approximated single ended crosstalk S-parameters.

In an implementation form, the measured subset of single ended S-parameters comprises single ended transmission S-parameters and/or single ended reflection S-parameters.

In an implementation form, the measurement unit of the system comprises a signal generator for generating electrical signals, wherein the electrical signals are forwarded to the DUT during the number of measurements via the number of ports; and wherein the measurement unit comprises a signal analyzer configured to analyze signals received from the DUT in response to the electrical signals.

In an implementation form, the system is a vector network analyzer.

According to a third aspect, the present disclosure relates to a method for determining single ended S-parameters of a device-under-test (DUT). The method comprises the steps of: performing a number of S-parameter measurements with the DUT to determine a subset of mixed-mode S-parameters of the DUT, wherein the subset of mixed-mode S-parameters are measured with a differential signal being applied to the DUT; approximating the remaining mixed-mode S-parameters of the DUT based on a model of the DUT or based on an assumption; and calculating the single ended mode S-parameters of the DUT based on the measured mixed-mode S-parameters and based on the approximated mixed-mode S-parameters.

According to a third aspect, the present disclosure relates to a system for determining single ended S-parameters of a device-under-test (DUT). The system comprises: a number of ports arranged for being connected to the DUT; a measurement unit configured to perform a number of S-parameter measurements with the DUT to determine a subset of mixed-mode S-parameters of the DUT, wherein the subset of mixed-mode S-parameters are measured with a differential signal being applied to the DUT; and a processor configured to approximate the remaining mixed-mode S-parameters of the DUT based on a model of the DUT or based on an assumption; wherein the processor is configured to calculate the single ended mode S-parameters of the DUT based on the measured mixed-mode S-parameters and based on the approximated mixed-mode S-parameters.

### BRIEF DESCRIPTION OF THE DRAWINGS

Exemplary embodiments of the disclosure are now further explained with respect to the drawings by way of example only, and not for limitation. In the drawings:

FIG. 1 shows a flow diagram of a method for determining mixed-mode S-parameters of a DUT according to an embodiment;

FIG. 2 shows a schematic diagram of a four port DUT according to an embodiment;

FIG. 3 shows a schematic diagram of a system for determining mixed-mode S-parameters of a DUT according to an embodiment;

FIG. 4 shows a flow diagram of a method for determining single ended S-parameters of a DUT according to an embodiment; and

FIG. 5 shows a schematic diagram of a DUT with a differential pair of transmission lines according to an embodiment.

### DETAILED DESCRIPTIONS OF EMBODIMENTS

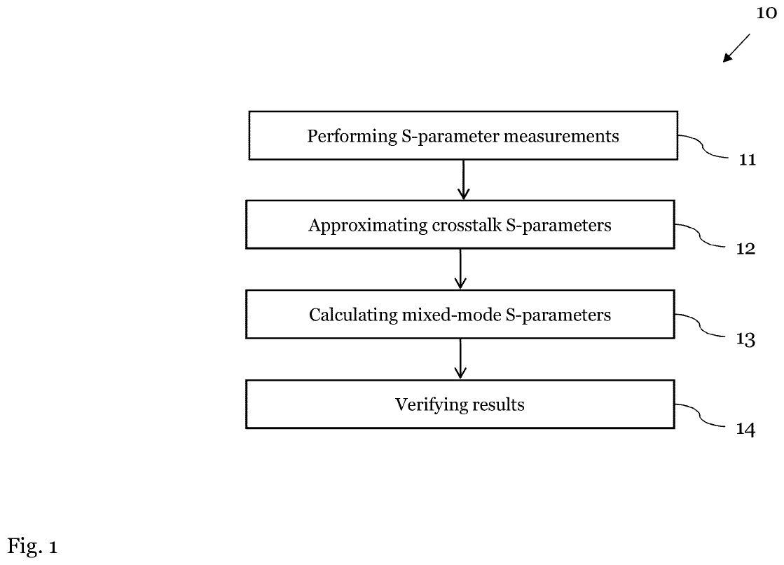

FIG. 1 shows a flow diagram of a method 10 for determining mixed-mode S-parameters of a DUT according to an embodiment.

The method 10 comprises the steps of: performing 11 a number of S-parameter measurements with the DUT to determine a subset of single ended S-parameters of the DUT, wherein the subset excludes single ended crosstalk S-parameters; approximating 12 the single ended crosstalk S-parameters of the DUT based on a model of the DUT or based on an assumption; and calculating 13 the mixed-mode S-parameters of the DUT based on the measured subset of single ended S-parameters and based on the approximated single ended crosstalk S-parameters.

For instance, when performing 11 the number of S-parameter measurements, the single ended crosstalk S-parameters of the DUT are not measured. These parameters are e.g. only approximated 12 based on the model of the DUT or based on the assumption.

The DUT can be a four-port device, i.e., a device with four ports that can receive or transmit an electrical signal.

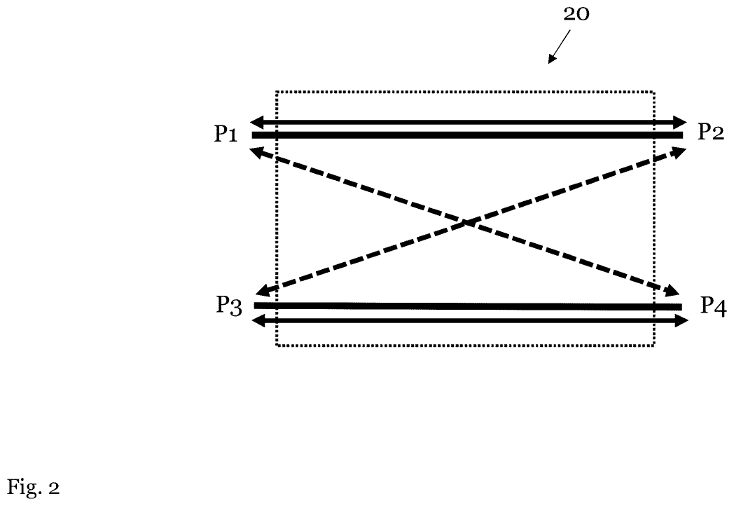

FIG. 2 shows a schematic diagram of such a four port DUT 20 according to an embodiment. This DUT 20 comprises the four ports P1, P2, P3 and P4. Thereby, ports P1 and P2 as well as ports P3 and P4 are connected by a signal line (bold gray lines in FIG. 2), indicating that the DUT 20 has two single ended transmission lines.

The measured subset of single ended S-parameters can comprise single ended transmission S-parameters and/or single ended reflection S-parameters. For instance, the transmission S-parameters characterize the intended signal paths through the DUT (i.e., from P1 to P2, from P2 to P1, from P3 to P4 and from P4 to P3), and the reflection S-parameters characterize the reflection from the DUT ports P1-P4. These signal paths are indicated by the bold arrows in FIG. 2 (parallel to the bold gray lines).

The crosstalk S-parameters (also referred to as: coupling S-parameters) characterize unwanted signal coupling into adjacent signal lines or channels of the DUT. This crosstalk between signals lines respectively channels is indicated by the dashed arrows in FIG. 2. The crosstalk S-parameters can be separated in near-end crosstalk (NEXT) and far-end crosstalk (FEXT) parameters.

For example, the DUT 20 can be or can comprise well characterized electric components (e.g., a well-known cable, connectors or backplanes on PCBs), such that the crosstalk S-parameters, which are often non-dominant parameters, can be considered as ideal or set to a fixed value. The DUT can be passive and/or reciprocal with respect to its ports respectively signal lines.

For instance, for such a four port DUT 20, the transmission S-parameters refer to the S₂₁, S₁₂, S₃₄ and S₄₃ coefficients, the reflection S-parameters refer to the S₁₁, S₂₂, S₃₃ and S₄₄ coefficients, and the crosstalk S-parameters refer to the S₁₃, S₁₃, S₂₃, S₂₄, S₃₁, S₃₂, S₄₁ and S₄₂ coefficients. Hereby, S₁₃, S₂₄, S₃₁ and S₄₂ are the NEXT parameters, and S₁₄, S₂₃, S₃₂ and S₄₁ are the FEXT parameters.

In a conventional scheme, these S-parameters can be measured by applying a well-known electrical signal to each port P1 to P4 one by one, and in each case recording the response at all ports P1 to P4. For instance, this can be done in four steps (e.g., step 1: electrical signal applied to P1, step 2: electrical signal applied to P2, step 3: electrical signal applied to P3, and step 4: electrical signal applied to P4). However, such a measurement routine can be time consuming as multiple measurements steps need to be carried out successively.

The method 10 as shown in FIG. 1 reduces the measurement effort and time for determining the S-parameters by only performing the main transmission and reflection measurements (indicated by the bold arrows) to calculate the transmission and reflection S-parameters and omitting the crosstalk measurements (indicated by the dashed arrows). Instead, the crosstalk measurements are approximated 12, e.g., based on data determined with a well-known DUT or based on model data or any other meaningful data. The transmission/reflection measurements can thereby be carried out in parallel, e.g. in two measurement steps (e.g., step 1: electrical signals applied to P1 and P3, and step 2: electrical signals applied to P2 and P4), to further increase the measurement speed.

The mixed-mode S-parameters can comprise differential-to-differential parameters (S_{dd}), common-to-common parameters (S_{cc}), differential-to-common parameters (S_{dc}), and common-to-differential (S_{cd}) parameters.

These mixed-mode S-parameters can be calculated from the calculated and approximated single ended S-parameters using the following conversion equations:

Sdd11=0.5(S11−S13−S31+S33)

Sdd12=0.5(S12−S14−S32+S34)

Sdd21=0.5(S21−S23−S41+S43)

Sdd22=0.5(S22−S24−S42+S44)

Scd11=0.5(S11−S13+S31−S33)

Scd12=0.5(S12−S14+S32−S34)

Scd21=0.5(S21−S23+S41−S43)

Scd22=0.5(S22−S24+S42−S44)

Sdc11=0.5(S11+S13−S31−S33)

Sdc12=0.5(S12+S14−S32−S34)

Sdc21=0.5(S21+S23−S41−S43)

Sdc22=0.5(S22+S24−S42−S44)

Scc11=0.5(S11+S13+S31+S33)

Scc12=0.5(S12+S14+S32+S34)

Scc21=0.5(S21+S23+S41+S43)

Scc22=0.5(S22+S24+S42+S44)

In the above equations, the single ended S-parameters in italics (S₁₃, S₁₄, S₂₃, S₂₄, S₃₁, S₃₂, S₄₁ and S₄₂) are the crosstalk parameters which are approximated in step 12, while the remaining single ended S-parameter are the transmission S-parameters (S₂₁, S₁₂, S₃₄ and S₄₃) and the reflection S-parameters (S₁₁, S₂₂, S₃₃ and S₄₄) which can be measured in step 11.

In step 13, all mixed-mode parameters, i.e. differential parameters (S_{dd}, S_{cc}) and mode conversion parameters (S_{dc}, S_{cd}), can be calculated. However, it is also possible that only the differential parameters (S_{dd}, S_{cc}) are calculated if these parameters are considered sufficient.

The approximation 12 of the crosstalk parameters can speed up the determination of the mixed-mode parameters by a factor of two compared to a conventional approach. At the same time, the method 10 allows maintaining compatibility with all relevant deembedding and post processing methods, such as TDR.

The single ended crosstalk S-parameters can be approximated as idealized parameter. For instance, the single ended crosstalk S-parameters are set to zero, as they are assumed to be the non-dominant parameters, while the single ended reflection and transmission parameters are assumed to be the dominant parameters.

The DUT 20 can be a digital design test (DDT) DUT. For such a DUT, appropriate assumptions for the single ended crosstalk S-parameters can be available.

The steps of the method 10 can be carried out by test and/or measurement system, such as a vector network analyzer (VNA).

Especially for digital design test scenarios, such as the characterization of a cable or data center solutions, the S-parameters measured by the described method 10 can correlate sufficiently well with tradition differential S-parameters for the relevant insertion and return loss measurements.

The method 10 may comprise the further step 14 of verifying the approximated single ended crosstalk S-parameters by correlating them with actual results, e.g. of a characterization measurement performed with the DUT. For instance, the characterization measurements can be carried out by the test and/or measurement system.

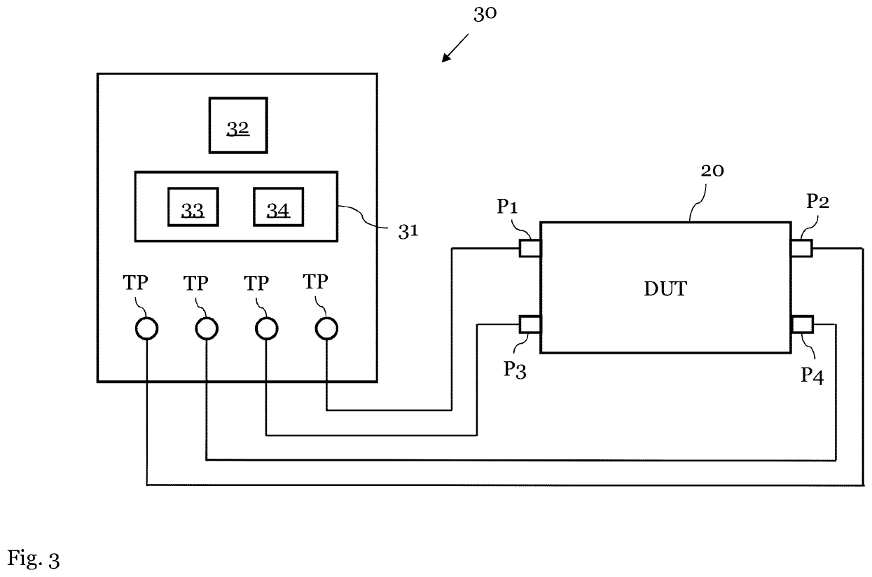

FIG. 3 shows a schematic diagram of a system 30 for determining the mixed-mode S-parameters of the DUT according to an embodiment. The system 30 can be a test and/or measurement system, such as a VNA.

The system 30 comprises: a number of ports TP arranged for being connected to the DUT 20; a measurement unit 31 configured to perform a number of S-parameter measurements with the DUT 20 to determine a subset of single ended S-parameters of the DUT, wherein the subset excludes single ended crosstalk S-parameters; and a processor 32 configured to approximate the single ended crosstalk S-parameters of the DUT based on the model of the DUT or based on the assumption; wherein the processor 32 is configured to calculate the mixed-mode S-parameters of the DUT 20 based on the measured single ended transmission and reflection S-parameters and based on the approximated single ended crosstalk S-parameters.

The measured subset of single ended S-parameters can comprise single ended transmission parameters and single ended reflection parameters of the DUT.

The ports TP can be test ports of the system 30. For instance, each port TP is connected to a respective port P1-P4 of the DUT 20 for performing the number of S-parameter measurements.

For example, the measurement unit 31 comprises a signal generator 33 for generating electrical signals, e.g. in the form of a radio frequency (RF) signal with known signal characteristics (e.g., frequency, amplitude, phase). The system 30 can forward these electrical signals to the DUT ports P1-P4 during the number of measurements via the number of ports TP.

The measurement unit 32 can further comprise a signal analyzer configured to analyze signals received from the DUT 20 in response to the electrical signals. For instance, these signals comprise reflections of the electrical signal from the DUT ports as well as transmissions of the electrical signal through the DUT (e.g., from P1 to P2 or from P3 to P4, or vice versa). The signal analyzer can compare the received signals to the electrical signals forwarded to the DUT 20 to calculate the single ended reflection and transmission S-parameters.

The signal analyzer 34 can be a further processor of the system. Alternatively, the signal analyzer 34 and the processor 31 can be formed by the same processing unit (e.g., a microprocessor).

The system 30 can be set to different measurement modes. For instance, in a differential measurement mode, the system only measures the single ended reflection and transmission S-parameters and approximates the crosstalk parameters. In another measurement mode, the system could carry out a conventional calculation of all single ended S-parameters (including crosstalk).

The differential measurement mode can be presented to the user as an alternative mode which is fully compatible with all relevant deembedding and post processing methods, such as TDR. This makes it very easy for users to speed up their measurement setups by a factor of two.

The system 30 could further comprise a memory which stores models of different DUTs or DUT types. These models can comprise crosstalk S-parameters of the respective DUT which can be used by the system 30 if an S-parameter measurement with a corresponding DUT is carried out.

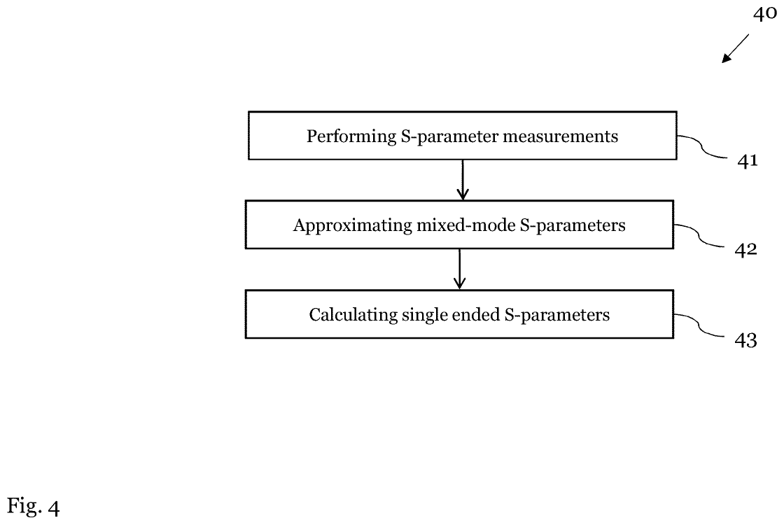

FIG. 4 shows a flow diagram of a method 40 for determining single ended S-parameters of a DUT according to an embodiment.

The method 40 comprises the steps of: performing 41 a number of S-parameter measurements with the DUT to determine a subset of mixed-mode S-parameters of the DUT, wherein the subset of mixed-mode S-parameters are measured with a differential signal being applied to the DUT; approximating 42 the remaining mixed-mode S-parameters of the DUT based on a model of the DUT or based on an assumption; and calculating 43 the single ended mode S-parameters of the DUT based on the measured mixed-mode S-parameters and based on the approximated mixed-mode S-parameters.

The subset of mixed-mode S-parameters which are measured with a differential signal being applied to the DUT may refer to the S_{dd} and S_{cd} parameters (i.e., the Sdd11, Sdd21, Sdd12, Sdd22, Scd11, Scd21, Scd12 and Scd22 coefficients).

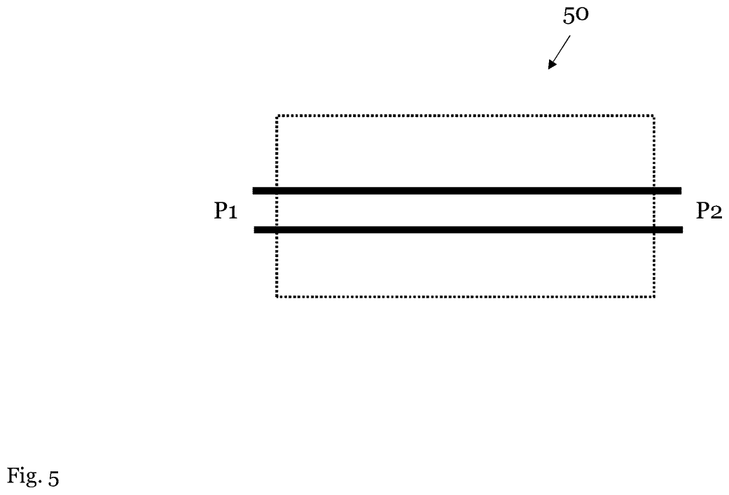

FIG. 5 shows a schematic diagram of a DUT 50 with a differential pair transmission line according to an embodiment. This DUT 50 is approximated to have two differential ports P1 and P2.

In a conventional measurement scheme, to measure mixed-mode S-parameters, each balanced port P1 and P2 transmits a differential (180° phase difference) and a common (0° phase difference) electrical signal one by one, and all signals are measured. For instance, this is done in four measurement steps (step 1: P1 receives 180° signal, step 2: P2 receives 180° signal, step 3: P1 receives 0° signal, step 4: P2 receives 0° signal).

The method 40 as shown in FIG. 4 reduces the measurement effort and time by omitting the common mode transmissions and performing only two steps with the main (wanted) differential signal and therefore save half of the measurement time. For instance, only four steps are required (step 1: P1 receives 180° signal, step 2: P2 receives 180° signal).

The common mode driven signal can be approximated with data, e.g., determined with a well-known DUT, or based on model data or any other meaningful data.

The single ended S-parameters can be calculated from the calculated and approximated mixed mode S-parameters using the following conversion equations:

S11=0.5(Sdd11+Scd11+Sdc11+Scc11)

S12=0.5(Sdd12+Scd12+Sdc12+Scc12)

S21=0.5(Sdd21+Scd21+Sdc21+Scc21)

S22=0.5(Sdd22+Scd22+Sdc22+Scc22)

S31=0.5(−Sdd11+Scd11−Sdc11+Scc11)

S32=0.5(−Sdd12+Scd12−Sdc12+Scc12)

S41=0.5(−Sdd21+Scd21−Sdc21+Scc21)

S42=0.5(−Sdd22+Scd22−Sdc22+Scc22)

S13=0.5(−Sdd11−Scd11+Sdc11+Scc11)

S14=0.5(−Sdd12−Scd12+Sdc12+Scc12)

S23=0.5(−Sdd21−Scd21+Sdc21+Scc21)

S24=0.5(−Sdd22−Scd22+Sdc22+Scc22)

S33=0.5(Sdd11−Scd11−Sdc11+Scc11)

S34=0.5(Sdd12−Scd12−Sdc12+Scc12)

S43=0.5(Sdd21−Scd21−Sdc21+Scc21)

S44=0.5(Sdd22−Scd22−Sdc22+Scc22)

In the above equations, the mixed mode S-parameters in italics are the approximated S-parameters (step 42), while the remaining S-parameters are measured in step 41.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

1. A method for determining mixed-mode S-parameters of a device-under-test, DUT, the method comprising the steps of:
performing a number of S-parameter measurements with the DUT to determine a subset of single ended S-parameters of the DUT, wherein the subset excludes single ended crosstalk S-parameters;
approximating the single ended crosstalk S-parameters of the DUT based on a model of the DUT or based on an assumption; and
calculating the mixed-mode S-parameters of the DUT based on the measured subset of single ended S-parameters and based on the approximated single ended crosstalk S-parameters.

2. The method of claim 1,
wherein the subset of single ended S-parameters comprises single ended transmission S-parameters and/or single ended reflection S-parameters.

3. The method of claim 1,
wherein the mixed-mode S-parameters comprise differential-to-differential parameters, common-to-common parameters, differential-to-common parameters, and/or common-to-differential parameters.

4. The method of claim 1,
wherein the single ended crosstalk S-parameters are approximated to be zero.

5. The method of claim 1, further comprising:
verifying the approximated single ended crosstalk S-parameters by correlating them with results of a characterization measurement performed with the DUT.

6. The method of claim 1,
wherein the DUT is a digital design test, DDT, DUT.

7. The method of claim 1,
wherein the DUT is a four-port device.

8. The method of claim 1,
wherein the steps of the method are carried out by a vector network analyzer.

9. A system for determining mixed-mode S-parameters of a device-under-test, DUT, comprising:
a number of ports arranged for being connected to the DUT;
a measurement unit configured to perform a number of S-parameter measurements with the DUT to determine a subset of single ended S-parameters of the DUT, wherein the subset excludes single ended crosstalk S-parameters; and
a processor configured to approximate the single ended crosstalk S-parameters of the DUT based on a model of the DUT or based on an assumption;
wherein the processor is configured to calculate the mixed-mode S-parameters of the DUT based on the measured subset of single ended S-parameters and based on the approximated single ended crosstalk S-parameters.

10. The system of claim 9,
wherein the measurement unit comprises a signal generator for generating electrical signals, wherein the electrical signals are forwarded to the DUT during the number of measurements via the number of ports; and
wherein the measurement unit comprises a signal analyzer configured to analyze signals received from the DUT in response to the electrical signals.

11. The system of claim 9,
wherein the system is a vector network analyzer.

12. The system of claim 9,
wherein the subset of single ended S-parameters comprises single ended transmission S-parameters and/or single ended reflection S-parameters.

13. The system of claim 9,
wherein the mixed-mode S-parameters comprise differential-to-differential parameters, common-to-common parameters, differential-to-common parameters, and/or common-to-differential parameters.

14. The system of claim 9,
wherein the single ended crosstalk S-parameters are approximated to be zero.

15. The system of claim 9,
wherein the processor is configured to verify the approximated single ended crosstalk S-parameters by correlating them with results of a characterization measurement performed with the DUT.

16. A method for determining single ended S-parameters of a device-under-test, DUT, the method comprising the steps of:
performing a number of S-parameter measurements with the DUT to determine a subset of mixed-mode S-parameters of the DUT, wherein the subset of mixed-mode S-parameters are measured with a differential signal being applied to the DUT;
approximating the remaining mixed-mode S-parameters of the DUT based on a model of the DUT or based on an assumption; and
calculating the single ended mode S-parameters of the DUT based on the measured mixed-mode S-parameters and based on the approximated mixed-mode S-parameters.

17. The method of claim 16,
wherein the single ended S-parameters comprises single ended transmission S-parameters and/or single ended reflection S-parameters.

18. The method of claim 16,
wherein the subset of the mixed-mode S-parameters comprise differential-to-differential parameters, common-to-common parameters, differential-to-common parameters, and/or common-to-differential parameters.

19. The method of claim 16,
wherein the DUT is a digital design test, DDT, DUT.

20. The method of claim 16,
wherein the DUT is a four-port device.
